(19) United States
(12) Patent Application Publication
(10) Pub. No.: US 2024/0213741 A1
(43) Pub. Date: Jun. 27, 2024

(54) DIE-LEVEL CURRENT RESONANT LASER DIODE DRIVER

(71) Applicant: Silanna Asia Pte Ltd, Singapore (SG)

(72) Inventors: Joseph H. Colles, Bonsall, CA (US); Steven E. Rosenbaum, San Diego, CA (US); Stuart B. Molin, Carlsbad, CA (US)

(73) Assignee: Silanna Asia Pte Ltd, Singapore (SG)

(21) Appl. No.: 18/540,393

(22) Filed: Dec. 14, 2023

Related U.S. Application Data
(60) Provisional application No. 63/476,821, filed on Dec. 22, 2022.

(51) Int. Cl. H01S 5/042; H01S 5/02345; H01S 5/026; H01S 5/062

(52) U.S. Cl. CPC H01S 5/0428; H01S 5/02345; H01S 5/0261; H01S 5/06216

(57) ABSTRACT

A pulsed laser diode driver includes a laser diode package having a first anode terminal, a cathode terminal, a laser diode, a first bond wire, and a second bond wire. A cathode of the laser diode is electrically connected to the cathode terminal, an anode of the laser diode is electrically connected to a first end of the first bond wire and to a first end of the second bond wire. A second end of the first bond wire is electrically connected to the first anode terminal, and a second end of the second bond wire is electrically connected to a capacitor. One or more switches are configured to control a current flow through the first and second bond wires to produce a high-current pulse through the laser diode, the high-current pulse corresponding to a peak current of a resonant waveform developed at the anode of the laser diode.

### RELATED APPLICATIONS

This application claims priority to U.S. Provisional Patent Application No. 63/476,821, filed Dec. 22, 2022, all of which is incorporated herein in its entirety.

### BACKGROUND

Laser-based ranging systems, such as Lidar, often use a pulsed laser diode driver circuit to generate a short high-current pulse which is passed through a laser diode to emit a corresponding pulse of laser light. Reflected pulses of laser light are received by the Lidar system and are used to determine a distance between the Lidar system and the point of reflection. The spatial resolution of a Lidar system is determined in part by the width of the pulse of laser light. Therefore, it is usually desirable to generate a pulse of light having a pulse width of about 5 ns or less.

Some pulsed laser driver circuits first develop a flux current through an inductor and then redirect the flux current through a laser diode as a high-current pulse, thereby resulting in light pulse emission. In some solutions, the inductor is a discrete surface-mounted or through-hole component.

### SUMMARY

In some aspects, the techniques described herein relate to a pulsed laser diode driver including: a source capacitor having i) a first terminal configured to receive a refresh current and to develop a source voltage therefrom, and ii) a second terminal electrically coupled to ground; a first laser diode package including a first anode terminal, a first cathode terminal, a first laser diode, a first bond wire, and a second bond wire, wherein a cathode of the first laser diode is directly electrically connected to the first cathode terminal, an anode of the first laser diode is directly electrically connected to a first end of the first bond wire and to a first end of the second bond wire, a second end of the first bond wire being directly electrically connected to the first anode terminal, and a second end of the second bond wire being electrically connected to the first terminal of the source capacitor; a bypass capacitor having a first terminal directly electrically connected to the first anode terminal of the first laser diode package; one or more switches configured to control a current flow through the first bond wire and the second bond wire; and a timing and control circuit configured to generate one or more gate driver signals to control the one or more switches to produce a high-current pulse through the first laser diode, the high-current pulse corresponding to a peak current of a resonant waveform developed at the anode of the first laser diode.

In some aspects, the techniques described herein relate to an apparatus, including: a first anode terminal, a second anode terminal, and a cathode terminal; a laser diode having an anode and a cathode, the cathode being electrically connected to the cathode terminal; a first bond wire having a first end that is directly electrically connected to the anode of the laser diode and a second end that is directly electrically connected to the first anode terminal; and a second bond wire having a first end that is directly electrically connected to the anode of the laser diode and a second end that is directly electrically connected to the second anode terminal.

In some aspects, the techniques described herein relate to an apparatus, including: an anode terminal and a cathode terminal; a laser diode having an anode and a cathode, the cathode being electrically connected to the cathode terminal; a first bond wire having a first end that is directly electrically connected to the anode of the laser diode and a second end that is directly electrically connected to the anode terminal; and a second bond wire having a first end that is directly electrically connected to the anode of the laser diode and a second end that is electrically connected to the cathode of the laser diode.

### BRIEF DESCRIPTION OF THE DRAWINGS

FIG. 1A is a simplified circuit schematic of a die-level current resonant pulsed laser diode driver of a first general topology, in accordance with some embodiments.

FIG. 1B is a simplified circuit schematic of a die-level current resonant pulsed laser diode driver of a second general topology, in accordance with some embodiments.

FIG. 2 is a simplified circuit schematic of a die-level current resonant pulsed laser diode driver of a third general topology, in accordance with some embodiments.

FIG. 3 is a simplified circuit schematic of a die-level current resonant pulsed laser diode driver of a fourth general topology, in accordance with some embodiments.

FIG. 4 is a simplified circuit schematic of a die-level current resonant pulsed laser diode driver of a fifth general topology, in accordance with some embodiments.

FIG. 5 shows simplified plots of signals related to the operation of the pulsed laser diode driver shown in FIG. 1A, in accordance with some embodiments.

FIG. 6 shows simplified plots of signals related to the operation of the pulsed laser diode driver shown in FIG. 2, in accordance with some embodiments.

FIG. 7 shows simplified plots of signals related to the operation of the pulsed laser diode driver shown in FIG. 3, in accordance with some embodiments.

FIG. 8 shows simplified plots of signals related to the operation of the pulsed laser diode driver shown in FIG. 4, in accordance with some embodiments.

FIG. 9 is a portion of an example switching sequence for the operation of the pulsed laser diode drivers shown in FIGS. 1A-4, in accordance with some embodiments.

FIG. 10 is a simplified, top-down orthoscopic view of a portion of a printed circuit board layout or laser diode package of the pulsed laser diode drivers shown in FIGS. 1A-2, in accordance with some embodiments.

FIG. 11 is a simplified, top-down orthoscopic view of a portion of a printed circuit board layout or laser diode package of the pulsed laser diode drivers shown in FIGS. 3-4, in accordance with some embodiments.

### DETAILED DESCRIPTION

Laser-based ranging systems, such as Lidar systems, often use a pulsed laser diode driver circuit to generate a short (e.g., 1-5 ns), high-current (e.g., 40 Amp) current pulse which is passed through a laser diode to emit a corresponding pulse of laser light. Some pulsed laser driver circuits first develop a flux current through an inductor and then redirect the current from the inductor along a second current path to produce a high-current pulse through a laser diode, thereby resulting in light pulse emission. In some solutions, the inductor is a discrete surface-mounted or through-hole-mounted component. However, such discrete inductors consume valuable circuit board area and increase the cost and complexity of a design. Disclosed herein are several general topologies of pulsed laser diode driver circuits that use one or more laser diode packages, or printed circuit boards, having a bond wire arrangement which obviates the use of a discrete inductor in the pulsed laser diode driver circuit.

Conventional laser diode packages include one or more laser diodes, each laser diode having a respective anode and cathode which are electrically connected to external pins or pads of the laser diode package. In some single laser diode packages, an anode of the laser diode is electrically connected to one or more pads or pins of the laser diode package, and a cathode of the laser diode is electrically connected to one or more pads or pins of the laser diode package. In common-cathode laser diode packages, each laser diode cathode is electrically connected to a single common cathode node (which may include multiple pads or pins to handle the combined current flow) of the laser diode package, and each laser diode anode is electrically connected to a respective individual anode terminal of the laser diode package. By comparison, in common-anode laser diode packages, each laser diode anode is electrically connected to a single common anode node of the laser diode package, and each laser diode cathode is electrically connected to a respective individual cathode terminal of the laser diode package. Some of the electrical connections within a laser diode package are implemented using bond wires while others are implemented using direct bonding to lead-frame pads of the laser diode package. Bond wires are typically made of Aluminum, Copper, Silver, or Gold and typically have a wire diameter ranging from 10 micrometers to several hundred micrometers.

The anode of a conventional laser diode is typically electrically connected to a single pad or pin of a laser diode package using one or more bond wires having design parameters (e.g., wire gauge and the number of wires) that are selected to reduce the inductance between the pad or pin and the anode. Though the inductance between the pad or pin of the laser diode package and the anode of the laser diode therein may be reduced, it is typically not eliminated. Therefore, conventional laser diode driver circuits are typically configured to mitigate the effects of what is considered to be a parasitic inductance (as compared to an intentionally added inductance).

In some embodiments, the laser diode package disclosed herein includes one or more first bond wires that electrically connect a laser diode anode within a laser diode package to a first pad or pin of a laser diode package. In some embodiments described herein, one or more second bond wires also electrically connect the laser diode anode to a second pad or pin of the laser diode package. In other embodiments described herein, the one or more second bond wires electrically connect the laser diode anode to the laser diode cathode.

In some embodiments, the laser diode package disclosed herein includes one or more first bond wires that electrically connect an anode of a laser diode to a first pad or pin of a direct die on printed circuit board (PCB). In some embodiments described herein, one or more second bond wires also electrically connect the laser diode anode to a second pad or pin of the PCB. In other embodiments described herein, the one or more second bond wires electrically connect the laser diode anode to the laser diode cathode.

As compared to conventional solutions, as disclosed herein the one or more first and second bond wires are selected by a designer to intentionally add inductance to a current path within the laser diode package rather than to reduce inductance for a current path within the laser diode package. Because a resonant circuit is created using components within the laser diode package itself, the driver is referred to herein as a die-level current resonant pulsed laser diode driver.

This bond wire arrangement advantageously allows flux current to flow directly through the bond wires from an energy storage capacitor of the laser diode driver circuit to develop energy in the bond wires in the form of magnetic flux. The current is made to increase in amplitude until it reaches a peak amplitude value, at which time it is redirected through the laser diode to emit a pulse of laser light. A switching sequence to drive the pulsed laser diode drivers disclosed herein is operable to generate a resonant waveform at an anode of the laser diode(s) to produce the high-current pulse through the laser diodes, a voltage level of the resonant waveform being advantageously sufficient to support the high-current pulse and not of a voltage level that exceeds the voltage required to generate the high-current pulse.

Because the bond wire arrangement provides a very low inductance, embodiments of such pulsed laser diode drivers can advantageously generate high-current pulses (e.g., 20 Amps) using a low input voltage (e.g., 3.5 V, 5V, 6V, 9V, 15V, etc.) and can thereby use Silicon-based switches, rather than GaN-based switches which are used by many conventional solutions. Any of the pulsed laser diode drivers disclosed herein can therefore be integrated into a single semiconductor die.

Embodiments of pulsed laser diode drivers disclosed herein advantageously use bond wires to intentionally add inductance to the pulsed laser diode driver to generate a resonant waveform. By contrast, conventional pulsed laser diode drivers often use a variety of techniques to overcome the effects of parasitic inductances of the bond wires of the pulsed laser diode driver and of the laser package diode itself and therefore teach away from intentionally adding yet additional inductance of the bond wires to the pulsed laser diode driver. In addition to such intentionally added inductance, the pulsed laser diode drivers disclosed herein advantageously include a bypass capacitor (or rely on the inherent capacitance of a bypass switch) that may be used by a designer to easily tune a desired pulse width emitted by the laser diode, as compared to conventional solutions which only have an energy storage capacitor, or that only consider non-tunable parasitic capacitances of the pulsed laser diode driver. Once again, such conventional solutions teach away from adding yet additional capacitance to the pulsed laser diode driver.

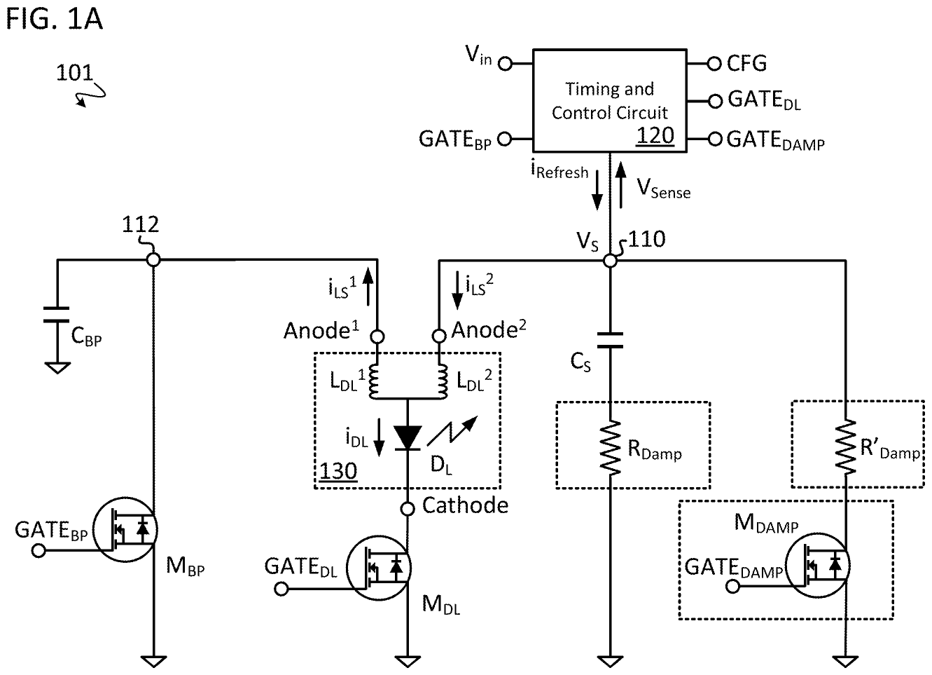

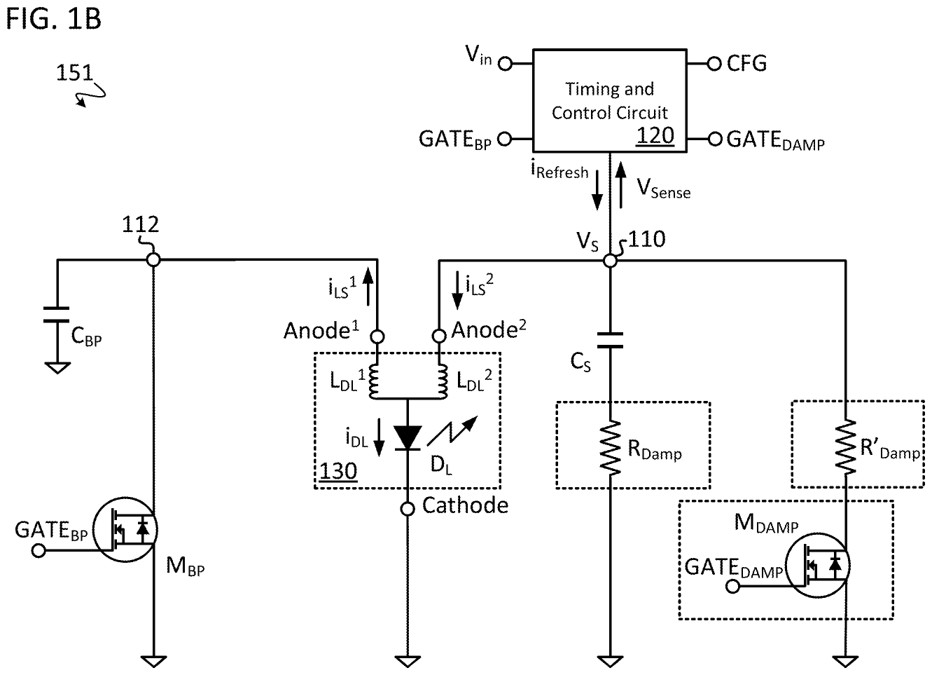

FIG. 1A is a simplified circuit schematic of a pulsed laser diode driver 101 of a first general topology to drive a laser diode package using a low-side switch, in accordance with some embodiments. The pulsed laser diode driver 101 generally includes an energy storage capacitor “source capacitor” C_{S} (i.e., a physical component that is not representative of a parasitic capacitance of another component), an optional damping resistor R_{Damp}, an alternative optional damping resistor R′_{Damp}, a laser diode package 130, a bypass switch M_{BP}, a bypass capacitor C_{BP} (i.e., either a physical component that is not representative of a parasitic capacitance of another component, or a drain capacitance of the bypass switch M_{BP}), a laser diode switch M_{DL}, and an optional discharge switch M_{DAMP}. The laser diode switch M_{DL} is configured as a low-side switch. In some embodiments, a drain capacitance of the bypass switch M_{BP} is of a sufficient value as to provide the bypass capacitance needed to achieve a desired pulse-width, and the bypass capacitor C_{BP} may therefore be omitted from the pulsed laser diode driver 101.

The laser diode package 130 includes one or more laser diodes D_{L}, each of which has a respective anode and cathode, a first bond wire L_{DL}¹, a second bond wire L_{DL}², a first anode terminal Anode¹, a second anode terminal Anode², and a common cathode terminal (“Cathode”). In some embodiments, the laser diode package 130 is implemented as a discrete component (i.e., the one or more laser diodes D_{L} and the bond wires L_{DL}¹⁻² are encapsulated in a package having respective external pads for the anode terminals Anode¹⁻² and the cathode terminal “Cathode”). In other embodiments, the laser diode package 130 is, or is part of, a direct die on printed circuit board device (i.e., the one or more laser diodes D_{L} are mounted on a printed circuit board, and the bond wires L_{DL}¹⁻² are connected to the laser diodes D_{L} and pads of the printed circuit board). In some embodiments, the assembled circuit board may be subsequently encapsulated.

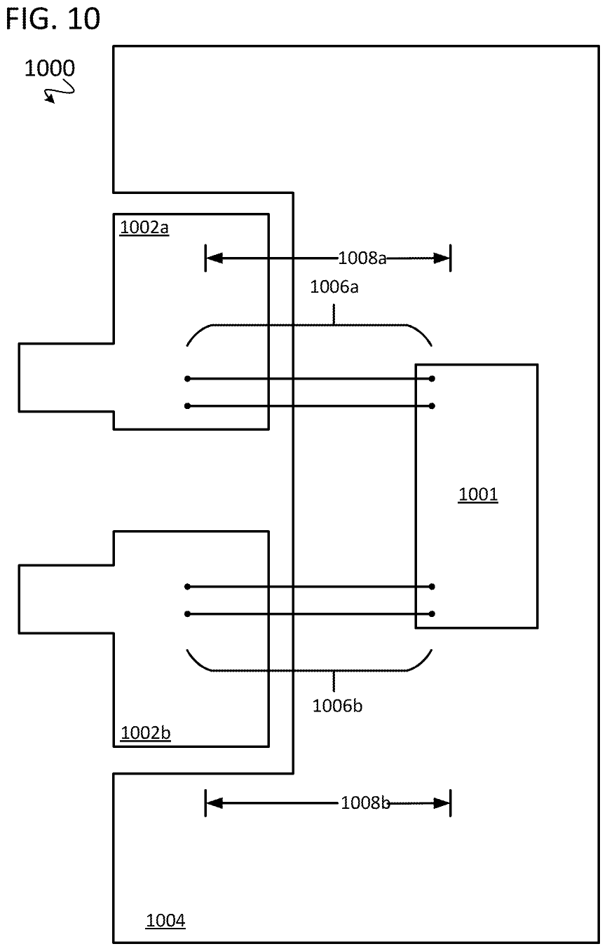

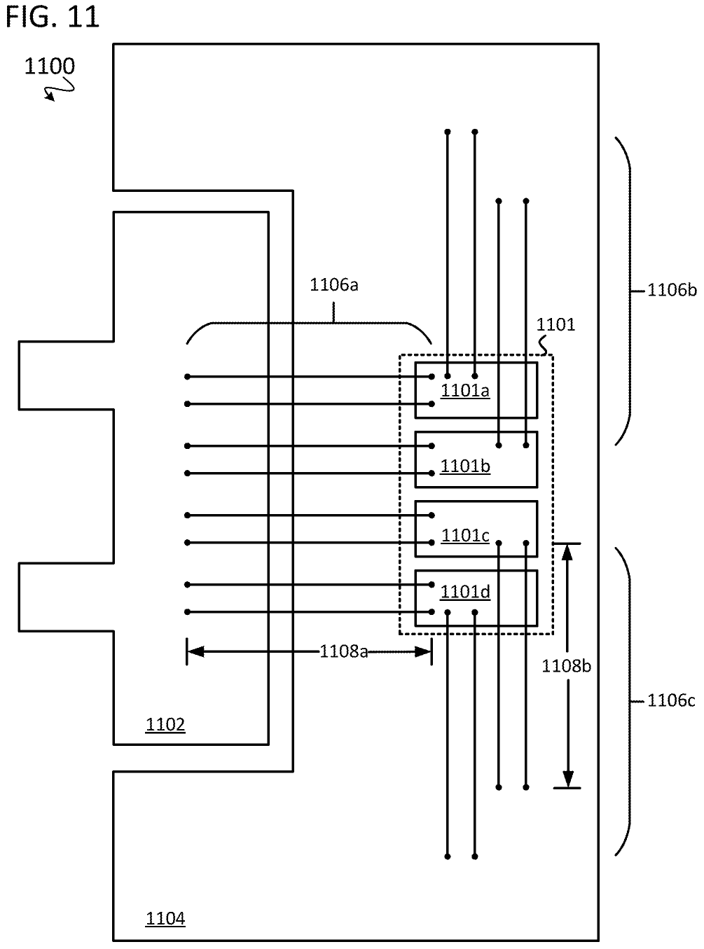

Though shown and referred to as respective single bond wires, in some embodiments, as shown in FIGS. 10-11, the first bond wire L_{DL}¹ may be implemented using a single bond wire, or two or more bond wires in parallel, to achieve a desired inductance value of the first bond wire L_{DL}¹. Similarly, as shown in FIG. 10-11, in some embodiments, the second bond wire L_{DL}² may be implemented using a single bond wire, or two or more bond wires in parallel, to achieve a desired inductance value of the second bond wire L_{DL}². In some embodiments, the total inductance of the second bond wire L_{DL}² is selected to be about twice the total inductance of the first bond wire L_{DL}¹. In other embodiments, as shown in FIGS. 10-11, the total inductance of the second bond wire L_{DL}² is selected to be the same as the total inductance of the first bond wire L_{DL}¹.

The first bond wire L_{DL}¹ electrically connects the anodes of the one or more laser diodes D_{L} to the first anode terminal Anode¹ of the laser diode package 130. The second bond wire L_{DL}² electrically connects the anodes of the one or more laser diodes D_{L} to the second anode terminal Anode² of the laser diode package 130. The cathodes of the one or more laser diodes D_{L} are electrically connected to the cathode terminal of the laser diode package 130 (e.g., using bond wires (not shown) or by mounting on a conductive pad).

Also shown is a timing and control circuit 120 which implements switch timing and control, nodes 110, 112, a refresh current i_{Refresh}, a voltage sense signal V_{Sense}, a DC input voltage Vᵢₙ, a source voltage Vs at the source capacitor C_{S}, a first fluxing current i_{LS}¹ through the first bond wire L_{DL}¹, a second fluxing current i_{LS}² through the second bond wire L_{DL}², a current i_{DL} through the one or more laser diodes D_{L}, a bypass switch gate driver signal GATE_{BP}, a laser diode switch gate driver signal GATE_{DL}, configuration data CFG, and a discharge switch gate driver signal GATE_{DAMP}.

In some embodiments, the configuration data CFG indicates parameters of the pulsed laser diode driver 101 that the timing and control circuit 120 uses when generating the gate driver signals used by the pulsed laser diode driver 101. For example, the configuration data CFG may indicate the number of laser diodes to be controlled, an electrical connection arrangement of the laser diodes, how the laser diodes should be controlled (e.g., simultaneously, sequentially, etc.), a desired pulse width, a desired time between pulses, a maximum voltage that the source capacitor C_{S} should be charged to, etc.

As shown in FIG. 1A, in some embodiments, the pulsed laser diode drivers disclosed herein include a series connection of the optional discharge switch M_{DAMP} and the alternative damping resistor R′_{Damp} connected in parallel to the source capacitor C_{S} thereof to rapidly discharge the source capacitor C_{S} when the discharge switch M_{DAMP} is enabled via the discharge switch gate driver signal GATE_{DAMP}. In such embodiments, the damping resistor R_{DAMP} may advantageously be excluded, and the source capacitor C_{S} is instead connected directly to ground instead of being coupled to ground through the damping resistor R_{DAMP}.

The timing and control circuit 120 may be integrated with any embodiment of the pulsed laser diode drivers disclosed herein, or it may be a circuit or module that is external to any embodiment of the pulsed laser diode drivers disclosed herein. The timing and control circuit 120 is operable to generate one or more gate drive signals having a voltage level that is sufficient to control (i.e., change the state of) the laser diode switch M_{DL}, the optional discharge switch M_{DAMP}, and the bypass switch M_{BP}. Additionally, the timing and control circuit 120 is operable to sense a voltage and/or current at any of the nodes 110 and 112 and at nodes that are similar to, or the same as, the nodes 110 and 112 as described herein, or at still other nodes of the pulsed laser diode drivers disclosed herein. The timing and control circuit 120 may include one or more timing circuits, look-up tables, processors, memory, or other modules to control the pulsed laser diode drivers disclosed herein. The refresh current i_{Refresh} flows from the timing and control circuit 120 to the source capacitor C_{S} to develop the source voltage Vs at the source capacitor C_{S}. The timing and control circuit 120 controls a current amplitude of the refresh current i_{Refresh} in response to a charge level (i.e., the source voltage Vs) of the source capacitor C_{S}. The amplitude of the refresh current i_{Refresh}, in turn, controls how quickly or slowly the source capacitor C_{S} is charged, or “refreshed”. While it is desirable that the source capacitor C_{S} be charged as quickly as possible, such rapid charging may result in undesirable voltage overshoot at the source capacitor C_{S}. Thus, one role of the timing and control circuit 120 is to optimize a charge rate of the source capacitor C_{S} while at the same time preventing voltage overshoot. The timing and control circuit 120 is additionally operable to control signal timing for the switch gate driver signals GATE_{DL}, GATE_{BP}, and GATE_{DAMP}. Charge rate optimization for the source capacitor C_{S} is described in detail in U.S. patent application Ser. No. 17/653,349, filed on Mar. 3, 2022, all of which is incorporated herein by reference in its entirety.

The timing and control circuit 120 is configured to be directly electrically connected to the DC input voltage Vᵢₙ. The DC input voltage Vᵢₙ may be a fixed voltage from a fixed voltage source or may be a voltage from a variable voltage source, such as from a digital-to-analog converter (DAC) (not shown). A voltage level of the DC input voltage Vᵢₙ may be set by the fixed or variable voltage source in accordance with a desired amplitude of a laser pulse emitted by the respective pulsed laser diode driver.

As shown in FIG. 1A, a first terminal of the source capacitor C_{S} is directly electrically connected to the timing and control circuit 120, and in some embodiments, a second terminal of the source capacitor C_{S} is directly electrically connected to a first terminal of the damping resistor R_{Damp}. A second terminal of the damping resistor R_{Damp} is directly electrically connected to a bias voltage node such as ground. Thus, the second terminal of the source capacitor C_{S} is electrically coupled to the bias voltage node.

A drain node of the bypass switch M_{BP} is directly electrically connected to the first anode terminal Anode¹ of the laser diode package 130 and a source node of the bypass switch M_{BP} is directly electrically connected to the bias voltage node. The second anode terminal Anode² of the laser diode package 130 is directly electrically connected to the timing and control circuit 120 and the first terminal of the source capacitor C_{S}. The cathode terminal of the laser diode package 130 is directly electrically connected to a drain node of the laser diode switch M_{DL}. A source node of the laser diode switch M_{DL} is directly electrically connected to the bias voltage node.

The bypass switch M_{BP} is configured to receive the bypass switch gate driver signal GATE_{BP} at a gate node, the bypass switch gate driver signal GATE_{BP} being operable to turn the bypass switch M_{BP} on or off based on a voltage level of the bypass switch gate driver signal GATE_{BP}. Similarly, the laser diode switch M_{DL} is configured to receive the laser diode switch gate driver signal GATE_{DL} at a gate node, the laser diode switch gate driver signal GATE_{DL} being operable to turn the laser diode switch M_{DL} on or off based on a voltage level of the laser diode switch gate driver signal GATE_{DL}. In some embodiments, the pulsed laser diode driver circuits disclosed herein include one or more bootstrap circuits or other level-shifting circuits to drive one or more high-side switches.

Either or both of the bypass switch M_{BP} and the laser diode switch M_{DL} can be implemented as N-type switches or P-type switches. In some embodiments, the bypass switch M_{BP} and the laser diode switch M_{DL} are implemented as Silicon-based or Silicon-Carbide-based field-effect transistors (FETs).

Two or more components described herein as having terminals that are directly electrically connected have a DC current path between the respective terminals of the two or more components. For example, a first and second component are not directly electrically connected via a capacitor or inductor connected in series between the first component and the second component.

In some embodiments, the pulsed laser diode driver 101 is configured to receive the DC input voltage Vᵢₙ having a voltage range from about 3.5 V to 20 V, which is advantageously lower than an input voltage used by many conventional pulsed laser diode drivers. As shown with reference to FIGS. 10-11, one or both of the bond wires L_{DL}¹ and L_{DL}² are configured (e.g., by adjusting a length, number, material, and/or diameter thereof) to add a desired amount of inductance in the current path of i_{LS}¹ and/or i_{LS}².

For some applications, the amplitude of a high-current pulse delivered by a resonant circuit such as any of those disclosed herein may need to be adjusted in amplitude from pulse-to-pulse. Thus, in some embodiments, any of the pulsed laser drivers disclosed herein are advantageously operable to configure an amplitude of the high-current pulse delivered to one or more laser diodes on a pulse-to-pulse basis. In such embodiments, the DC input voltage Vᵢₙ is advantageously provided by an adjustable voltage supply (i.e., a digital-to-analog converter (DAC)) (not shown). In some embodiments, an output voltage level of the adjustable voltage supply is set using the timing and control circuit 120. Use of an adjustable voltage supply, such as a DAC, to provide the DC input voltage Vᵢₙ to the pulsed laser diode driver circuits disclosed herein is possible because of the advantageously low input voltage requirements for such embodiments. In some embodiments, the adjustable voltage supply is controlled such that the adjustable voltage supply charges the source capacitor C_{S} described herein only during a first portion of a switching cycle. As such, the value of the DC input voltage Vᵢₙ and a current amplitude of the high-current pulse delivered to the laser diode(s) disclosed herein may be advantageously varied between consecutive high-current pulses through the laser diode(s).

As disclosed herein, values of the DC input voltage Vᵢₙ, the inductance of the bond wires L_{DL}¹ and L_{DL}², the capacitance of the source capacitor C_{S}, the resistance of the damping resistor R_{Damp} (if used), the resistance of the alternative damping resistor R′_{Damp} (if used), and the capacitance of the bypass capacitor C_{BP} can advantageously be selected (“tuned”) to achieve a desired operation of the pulsed laser diode driver 101 (e.g., a charge time, a pulse width, a pulse voltage, and/or a peak pulse current). For example, a pulse width of the current i_{DL} flowing through the one or more laser diodes D_{L} can be tuned by adjusting the capacitance value of the bypass capacitor C_{BP}. A peak current level of the pulse of current i_{DL} flowing through the laser diodes D_{L} can be tuned by adjusting the source voltage Vs on the source capacitor C_{S}. A capacitance value of the source capacitor C_{S} can be selected to adjust a timing delay of the current pulse and an upper range of the current i_{DL} through the laser diodes D_{L}.

A resistance value of the damping resistor R_{Damp}, if used, is selected based on the capacitance value of the source capacitor C_{S} and can be tuned within a range of values such that at a lower resistance, a lower frequency resonance of the pulsed laser diode drivers disclosed herein is underdamped (e.g., at about R_{Damp}=0.1 Ohm), or is critically damped (e.g., at about R_{Damp}=0.4 Ohm). The optional damping resistor R_{Damp} is operable to prevent current of the generated resonant waveform from becoming negative which could thereby enable a body diode of the bypass switch M_{BP} or the laser diode switch M_{DL}. Although a resulting maximum current level of the current i_{DL} through the laser diode D_{L} is lower for the critically damped case, the current level can be easily adjusted by raising the voltage level of the DC input voltage Vᵢₙ. In other embodiments, the damping resistor R_{Damp} is removed entirely from the design (i.e., the second terminal of the source capacitor C_{S} is directly electrically connected to the bias voltage node). In yet other embodiments, the resistance value of the damping resistor R_{Damp} is set to zero Ohms. As disclosed herein, as such values are adjusted, or tuned, the timing and control circuit 120 is advantageously operable to adjust a timing of gate control signals of the pulsed resonant laser diode driver circuits disclosed herein such that an “inductor current” through the first and second bond wires L_{DL}¹ and L_{DL}² is directed through the laser diodes D_{L} when the inductor current is at a maximum amplitude.

In some or all of the embodiments disclosed herein, to produce around a 40 A high-current pulse through the one or more laser diodes D_{L}, the DC input voltage Vᵢₙ may range from 3.5-45 volts. In some such embodiments, the inductance of the first bond wire L_{DL}¹ ranges from about 1 nH to 2 nH, and the inductance of the second bond wire L_{DL}² ranges from about 1 nH to 2 nH, the values of which determine the amount of flux delay to produce the required current. In some embodiments, the resistance of the damping resistor R_{Damp} ranges from 100-200 mOhms.

A capacitance value of the bypass capacitor C_{BP} (or of the bypass switch M_{BP}) determines the pulse width of the high-current pulse through the laser diode(s) D_{L}, and in some embodiments ranges in capacitance from 1-5 nF. In some such embodiments, a capacitance of the source capacitor C_{S} ranges from 25-100 nF depending on a peak current of the high-current pulse through the laser diodes D_{L} that is required or desired. The smaller the source capacitor C_{S}, the higher the DC input voltage Vᵢₙ is needed to get the required or desired peak current of the high-current pulse through the laser diodes D_{L}. In some such embodiments, a smallest capacitance value of the source capacitor C_{S} that can still deliver the needed or desired peak current of the high-current pulse through the laser diodes D_{L} is selected because all the remaining energy after the high-current pulse is shunted to ground and is wasted, thereby lowering a power efficiency of the pulsed laser diode driver. For a typical 1 mm bond wire, a 1 nF bypass capacitor will yield approximately a pulse width of 2-3 ns assuming that the pulse width is equal to 2π\sqrt{LC}.

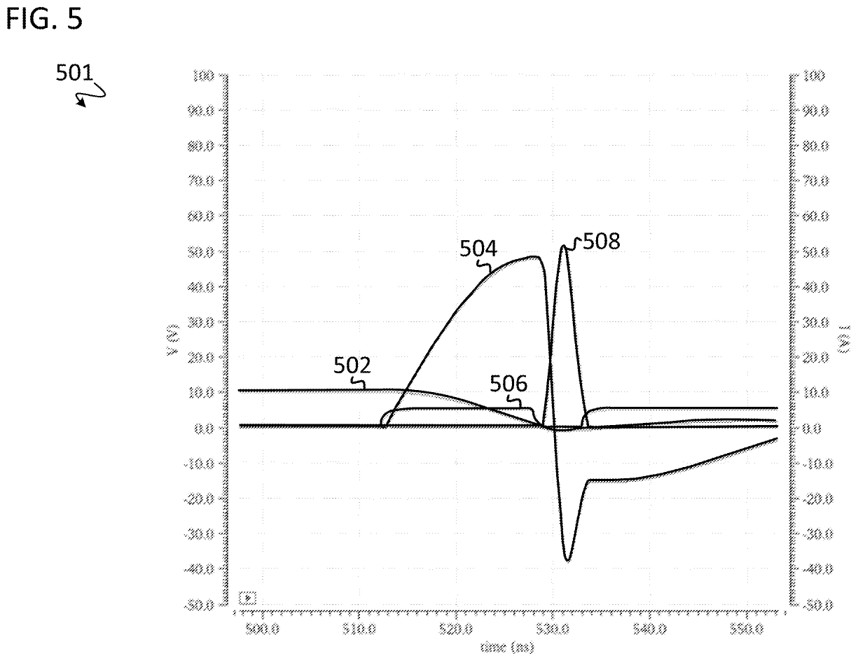

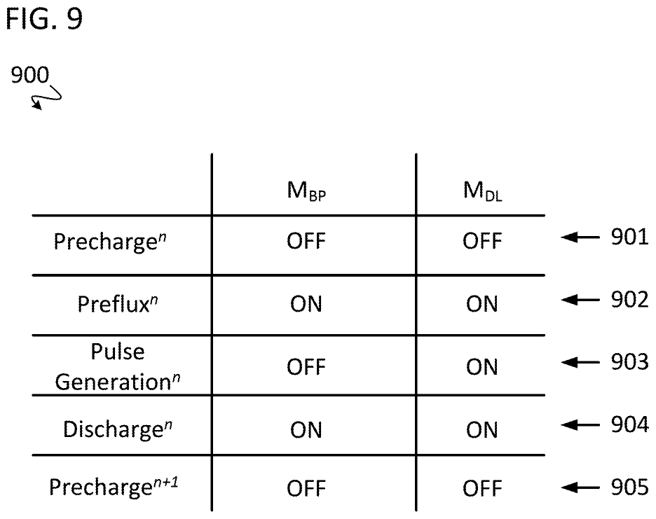

Operation of the pulsed laser diode driver 101 is explained in detail below with reference to a simplified plot 501 shown in FIG. 5 and is similar to or the same as the example switching sequence 900 that is shown in FIG. 9.

Though the respective inductances of L_{DL}¹⁻² are described herein as being advantageously implemented using bond wires, use of discrete inductors is not precluded. That is, in some embodiments, the circuit architecture of the pulsed laser diode driver 101 could use discrete inductors to implement the inductances of L_{DL}¹ and L_{DL}². For example, in some instances, the circuit architecture of the pulsed laser diode driver 101 may convey advantages (e.g., for achieving a particular current pulse width or current pulse amplitude through the laser diodes D_{L}) that are independent of whether the inductances of L_{DL}¹ and L_{DL}² are implemented using bond wires or discrete inductors.

FIG. 1B is a simplified circuit schematic of a pulsed laser diode driver 151 of a second general topology to drive a laser diode package, in accordance with some embodiments. The pulsed laser diode driver 151 includes all of the elements of the pulsed laser diode driver 101 introduced in FIG. 1A, with the exception of the laser diode switch M_{DL} which is advantageously omitted in the embodiment shown. Such embodiments may omit the laser diode switch M_{DL} so long as the source capacitor C_{S} is charged to a voltage such that the threshold voltage of the laser diode D_{L} is not surpassed during a fluxing stage of the pulsed laser diode driver 151, since the laser diode D_{L} will be forward biased (i.e., during steps 901 and 902 described with reference to FIG. 9). For example, the pulsed laser diode driver 151 is compatible with a source voltage Vs of about 3.5V to a maximum 10V. This is because when the source voltage Vs, is for example, 5V, a voltage at the anode of the laser diode D_{L} will be about 2.5 V, which is still below a typical 6.5 V threshold voltage of the laser diode D_{L}.

In addition to having an advantageously simplified design due to the omission of the laser diode switch M_{DL}, the pulsed laser diode driver 151 is operable to drive multiple (e.g., two, four, eight, 16, 32, 64, and so on) laser diode packages 130 simultaneously in parallel using a single source capacitor C_{S} and bypass switch M_{BP}. The pulsed laser diode driver 151 is additionally operable to drive one or more laser diode packages 130 that include multiple laser diodes (e.g., a quad-pack), all laser diodes of the laser diode package 130 being pulsed in unison.

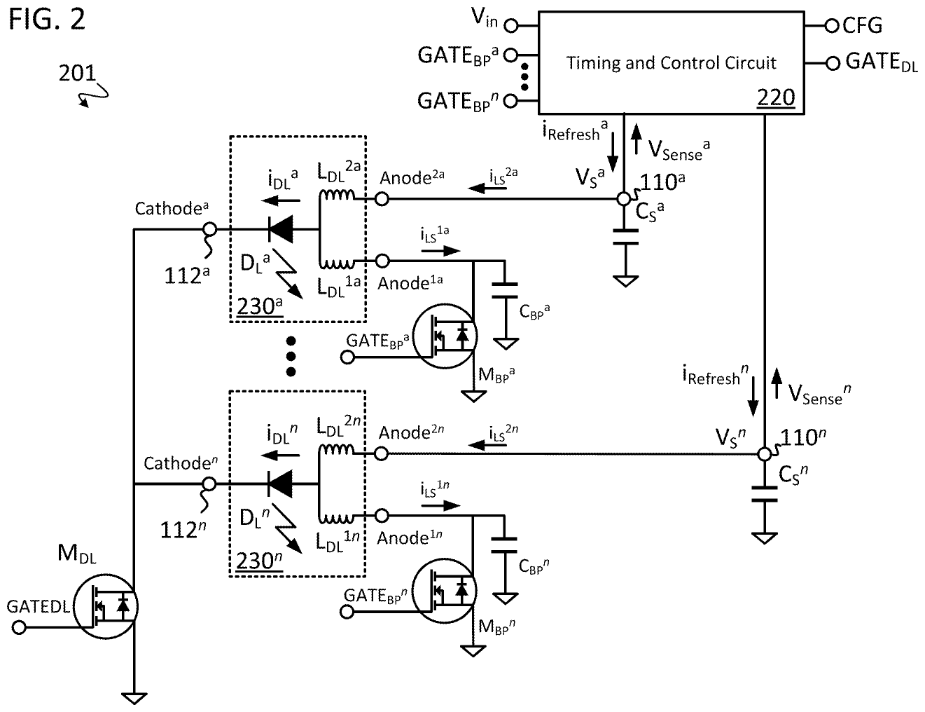

FIG. 2 is a simplified circuit schematic of a pulsed laser diode driver 201 of a third general topology to independently drive n channels (i.e., either two or more laser diode packages, or a single laser diode package having multiple laser diodes) in a common cathode arrangement using a low-side switch, in accordance with some embodiments. Some components described above with reference to FIG. 1A are included in FIG. 2. The pulsed laser diode driver 201 generally includes n source capacitors C_{S}^{a-n}, n laser diode packages 230^{a-n}, n bypass capacitors C_{BP}^{a-n}, n bypass switches M_{BP}^{a-n}, the laser diode switch M_{DL}, a timing and control circuit 220 that is similar to the timing and control circuit 120, nodes 110^{a-n}, nodes 112^{a-n}, n refresh currents i_{Refresh}^{a-n}, n voltage sense signals V_{Sense}^{a-n}, the DC input voltage Vᵢₙ, n respective source voltages V_{S}^{a-n} at the source capacitors C_{S}^{a-n}, n bypass switch gate driver signals GATE_{BP}^{a-n}, the laser diode switch gate driver signal GATE_{DL}, and the configuration data CFG, connected as shown. In some embodiments, a respective drain capacitance of the bypass switches M_{BP}^{a-n} is of a sufficient value as to provide the bypass capacitances needed, and the bypass capacitors C_{BP}^{a-n} may therefore be omitted from the pulsed laser diode driver 201. Additionally, to simplify the description of the pulsed laser diode driver 201, the optional damping resistor R_{Damp}, the alternative optional damping resistor R′_{Damp}, and the optional discharge switch M_{Damp} have been omitted from FIG. 2. However, in some embodiments, each channel of the n channels of the pulsed laser diode driver 201 includes a respective discharge switch (not shown) having a drain node that is connected to a first terminal of the source capacitor of that channel and a source node that is connected to a bias voltage such as ground.

In some embodiments, each of the laser diode packages 230^{a-n} are respective individual laser diode packages. In other embodiments, the laser diode packages 230^{a-n} are part of a single package (e.g., a quad-pack) of laser diodes. In such embodiments, the cathode terminals Cathode^{a-n} may be implemented as a single pad or pin of the laser diode package (i.e., a common-cathode arrangement), and the anode terminals Anode^{1a-2a} through Anode^{1a-2a} may each be implemented as respective individual pads or pins of the laser diode package.

Of the n laser diode packages 230^{a-n}, the laser diode package 230^{a} includes one or more laser diodes D_{L}^{a}, each having a respective anode and cathode, a first bond wire L_{DL}^{1a}, a second bond wire L_{DL}^{2a}, a first anode terminal Anode^{1a}, a second Anode terminal Anode^{2a}, and a common cathode terminal Cathode^{a}. Though shown and referred to as respective single bond wires, as shown in FIGS. 10-11 in some embodiments, the first bond wire L_{DL}^{1a} may be implemented using a single bond wire, or two or more bond wires in parallel, to achieve a desired inductance value of the first bond wire L_{DL}^{1a}. Similarly, in some embodiments, the second bond wire L_{DL}^{2a} may be implemented using a single bond wire, or two or more bond wires in parallel, to achieve a desired inductance value of the second bond wire L_{DL}^{2a}. The first bond wire L_{DL}^{1a} electrically connects the anodes of the laser diodes D_{L}^{a} to the first anode terminal Anode^{1a} of the laser diode package 230^{a}. The second bond wire L_{DL}^{2a} electrically connects the anodes of the laser diodes D_{L}^{a} to the second anode terminal Anode^{2a} of the laser diode package 230^{a}. The cathodes of the laser diodes D_{L}^{a} are electrically connected to the cathode terminal of the laser diode package 230^{a} (e.g., using bond wires (not shown) or by mounting on a conductive pad). Also shown is a first fluxing current i_{LS}^{1a} through the bond wire L_{DL}^{1a}, second fluxing current i_{LS}^{2a} through the bond wire L_{DL}^{2a}, and a current i_{DL}^{a} through the laser diodes D_{L}^{a}. One or both of the bond wires L_{DL}^{1a} and L_{DL}^{2a} are configured (e.g., by adjusting a length, number, material, and/or diameter thereof) to add a desired amount of inductance in the current path of i_{LS}^{1a} and/or i_{LS}^{2a}.

Similarly, the laser diode package 230ⁿ includes one or more laser diodes D_{L}ⁿ, each having a respective anode and cathode, a first bond wire L_{DL}¹ⁿ, a second bond wire L_{DL}²ⁿ, a first anode terminal Anode¹ⁿ, a second Anode terminal Anode²ⁿ, and a cathode terminal Cathodeⁿ. Though shown and referred to as respective single bond wires, in some embodiments, the first bond wire L_{DL}¹ⁿ may be implemented using a single bond wire, or two or more bond wires in parallel, to achieve a desired inductance value of the first bond wire L_{DL}¹ⁿ. Similarly, in some embodiments, the second bond wire L_{DL}²ⁿ may be implemented using a single bond wire, or two or more bond wires in parallel, to achieve a desired inductance value of the second bond wire L_{DL}²ⁿ. The first bond wire L_{DL}¹ⁿ electrically connects the anodes of the laser diodes D_{L}ⁿ to the first anode terminal Anode¹ⁿ of the laser diode package 230ⁿ. The second bond wire L_{DL}²ⁿ electrically connects the anodes of the laser diodes D_{L}ⁿ to the second anode terminal Anode²ⁿ of the laser diode package 230ⁿ. The cathodes of the laser diode D_{L}ⁿ are electrically connected to the cathode terminal of the laser diode package 230ⁿ (e.g., using bond wires (not shown) or by mounting on a conductive pad). Also shown is a first fluxing current i_{LS}¹ⁿ through the bond wire L_{DL}¹ⁿ, a second fluxing current i_{LS}²ⁿ through the bond wire L_{DL}²ⁿ, and a current i_{DL}ⁿ through the laser diode D_{L}ⁿ. One or both of the bond wires L_{DL}¹ⁿ and L_{DL}²ⁿ are configured (e.g., by adjusting a length, number, material, and/or diameter thereof) to add a desired amount of inductance in the current path of i_{LS}¹ⁿ and/or i_{LS}²ⁿ.

In some embodiments, the DC input voltage Vᵢₙ is about 15 V, the respective inductance of the first bond wires LDL^{1a-n} is about 1-2 nH, the respective inductance of the second bond wires L_{DL}^{2a-n} is about 1-2 nH, the respective capacitance of the source capacitors C_{S}^{a-n} is about 10-50 nF, and the respective capacitances of the bypass capacitor C_{BP}^{a-n} is about 1 nF.

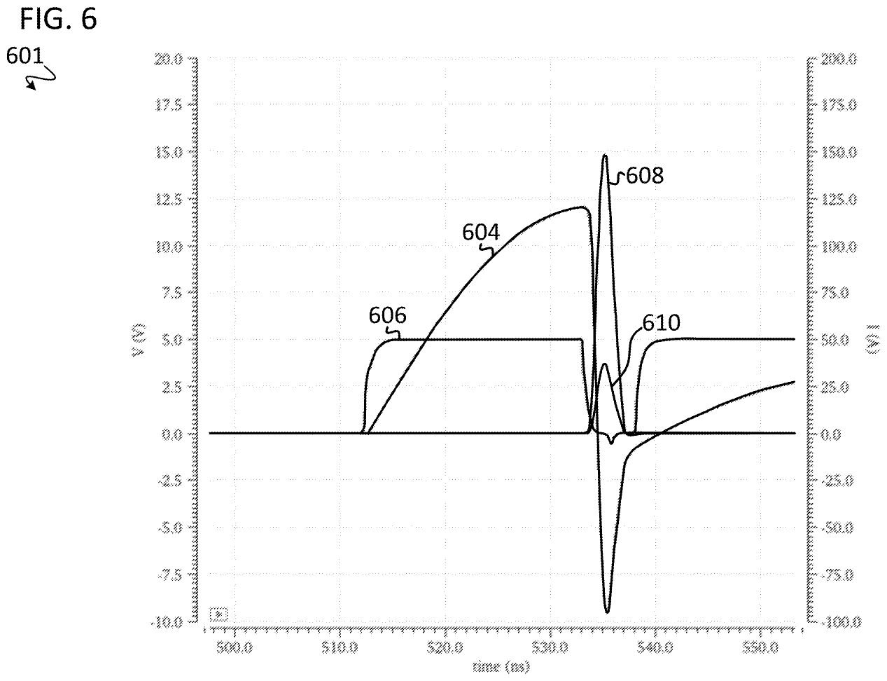

The timing and control circuit 220 is operable to generate one or more gate drive signals having a voltage level that is sufficient to control (i.e., change the state of) the laser diode switch M_{DL} and the bypass switches M_{BP}^{a-n}. Operation of the pulsed laser diode driver 201 is explained in detail below with respect to a simplified plot 601 shown in FIG. 6 and is similar to or the same as the example switching sequence 900 that is shown in FIG. 9.

Though the respective inductances of L_{DL}^{1a-2a} and L_{DL}¹⁻²ⁿ are described herein as being advantageously implemented using bond wires, use of discrete inductors is not precluded. That is, in some embodiments, the circuit architecture of the pulsed laser diode driver 201 could use discrete inductors to implement the inductances of L_{DL}^{1a-2a} and L_{DL}¹ⁿ⁻²ⁿ. For example, in some instances, the circuit architecture of the pulsed laser diode driver 201 may convey advantages (e.g., for achieving a particular current pulse width or current pulse amplitude through the laser diodes D_{L}) that are independent of whether the inductances of L_{DL}^{1a-2a} and L_{DL}¹ⁿ⁻²ⁿ are implemented using bond wires or discrete inductors.

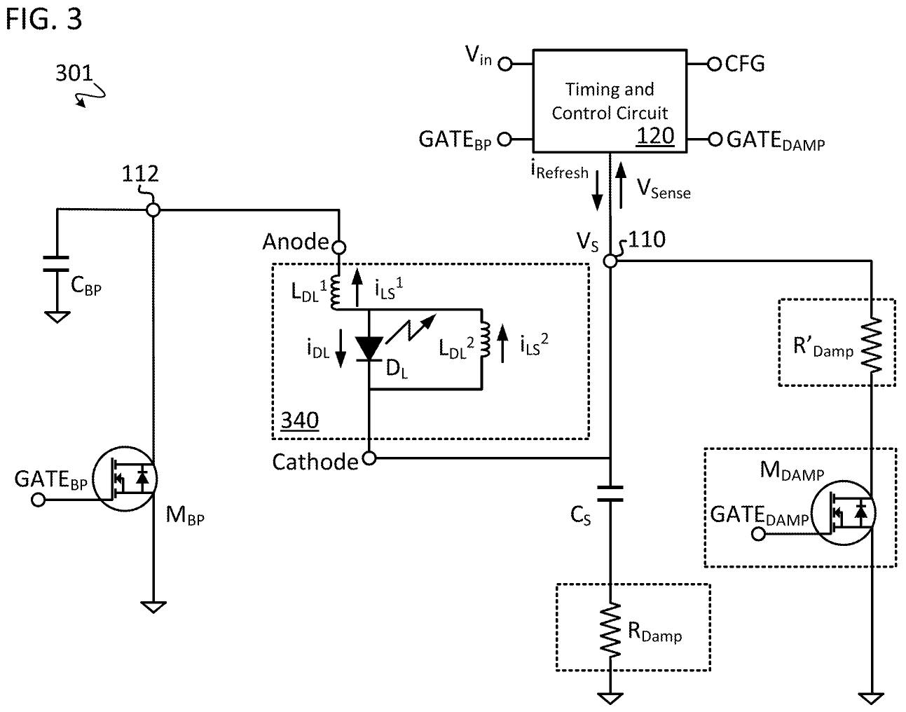

FIG. 3 shows a simplified circuit schematic of a pulsed laser diode driver 301 of a fourth general topology, in accordance with some embodiments. Some components described above with reference to FIG. 1A are included in FIG. 3. The pulsed laser diode driver 301 generally includes the source capacitor C_{S}, the optional damping resistor R_{Damp}, the alternative optional damping resistor R′_{Damp}, a laser diode package 340, the bypass capacitor C_{BP}, the bypass switch M_{BP}, the timing and control circuit 120, the optional discharge switch M_{DAMP}, the timing and control circuit 120, the nodes 110, 112, the refresh current i_{Refresh}, the voltage sense signal V_{Sense}, the DC input voltage Vᵢₙ, the source voltage Vs at the source capacitor C_{S}, the bypass switch gate driver signal GATE_{BP}, the configuration data CFG, and the discharge switch gate driver signal GATE_{DAMP}. In some embodiments, a drain capacitance of the bypass switch M_{BP} is of a sufficient value as to provide the bypass capacitance needed, and the bypass capacitor C_{BP} may therefore be omitted from the pulsed laser diode driver 301.

The laser diode package 340 includes one or more laser diodes D_{L}, each having a respective anode and cathode, a first bond wire L_{DL}¹, a second bond wire L_{DL}², an anode terminal (“Anode”), and a cathode terminal (“Cathode”). In some embodiments, the laser diode package 340 is implemented as a discrete component (i.e., the one or more laser diodes D_{L} and the bond wires L_{DL}¹⁻² are encapsulated in a package having respective external pads for the anode terminal “Anode” and the cathode terminal “Cathode”. In other embodiments, the laser diode package 340 is, or is part of, a direct die on printed circuit board device (i.e., the one or more laser diodes D_{L} are mounted on a printed circuit board, and the bond wires L_{DL}¹⁻² are connected to the laser diodes D_{L} and pads of the printed circuit board). In some embodiments, the assembled circuit board may be subsequently encapsulated.

Because the laser diode DI is reverse-biased during a fluxing stage of the pulsed laser diode driver 301 (i.e., during steps 901 and 902 described with reference to FIG. 9), the pulsed laser diode driver 301 supports a wide range of source voltage Vs values, e.g., 3.5V-45V as the laser diode D_{L} will not become forward biased until light pulse emission. During pulse emission, the Cathode node of the pulsed laser diode driver circuit 301 reaches a voltage level of about negative one-half times the source voltage Vs and the Anode node is at about 0 volts, thereby forward biasing the laser diodes D_{L}.

Though shown and referred to as respective single bond wires, as shown in FIGS. 10-11, in some embodiments, the first bond wire L_{DL}¹ may be implemented using a single bond wire, or two or more bond wires in parallel, to achieve a desired inductance value of the first bond wire L_{DL}¹. Similarly, in some embodiments, the second bond wire L_{DL}² may be implemented using a single bond wire, or two or more bond wires in parallel, to achieve a desired inductance value of the second bond wire L_{DL}². In some embodiments, the inductance value of the second bond wire L_{DL}² is about twice that of the first bond wire L_{DL}¹. In other embodiments, the inductance of the second bond wire L_{DL}² is the same as that of the first bond wire L_{DL}¹.

The first bond wire L_{DL}¹ electrically connects the anodes of the laser diodes D_{L} to the anode terminal of the laser diode package 340. The second bond wire L_{DL}² electrically connects the anodes of the laser diodes D_{L} to the cathodes of the laser diodes D_{L}. The cathodes of the laser diodes D_{L} are also electrically connected to the cathode terminal of the laser diode package 340 (e.g., using bond wires (not shown) or by mounting on a conductive pad).

As shown in FIG. 3, a first terminal of the source capacitor C_{S} is configured to receive the refresh current i_{Refresh} from the timing and control circuit 120. The first terminal of the source capacitor C_{S} is directly electrically connected to the cathode terminal of the laser diode package 340 and is electrically coupled to a first terminal of the bypass capacitor C_{BP} and to a drain node of the bypass switch M_{BP} via the bond wires L_{DL}¹⁻². A second terminal of the source capacitor C_{S} is directly electrically connected to a bias voltage node such as ground, or is electrically coupled to a bias voltage node such as ground through the optional damping resistor R_{Damp}. A second terminal of the optional damping resistor R_{Damp}, a second terminal of the discharge switch M_{DAMP}, and a second terminal of the bypass capacitor C_{BP} are directly electrically connected to a bias voltage node such as ground. The anode terminal of the laser diode package 340 is directly electrically connected to the first terminal of the bypass capacitor C_{BP} and to a drain node of the bypass switch M_{BP}. A source node of the bypass switch M_{BP} is directly electrically connected to a bias voltage node such as ground.

The bypass switch M_{BP} is configured to receive the bypass switch gate driver signal GATE_{BP} at a gate node (e.g., from the timing and control circuit 120), the bypass switch gate driver signal GATE_{BP} being operable to turn the bypass switch M_{BP} on or off based on a voltage level of the bypass switch gate driver signal GATE_{BP}. Similarly, the optional discharge switch M_{DAMP} is configured to receive the discharge switch gate driver signal GATE_{DAMP} at a gate node (e.g., from the timing and control circuit 120), the discharge switch gate driver signal GATE_{DAMP} being operable to turn the discharge switch M_{DAMP} on or off based on a voltage level of the discharge switch gate driver signal GATE_{DAMP}.

Either or both of the bypass switch M_{BP} and/or the discharge switch M_{DAMP} can be implemented as N-type switches or P-type switches. In some embodiments, the bypass switch M_{BP} and/or the discharge switch M_{DAMP} are implemented as Silicon-based or Silicon-Carbide-based field-effect transistors (FETs).

In some embodiments, the pulsed laser diode driver 301 is configured to receive the DC input voltage Vᵢₙ having a voltage range from about 3.5 V to 45 V, which is advantageously lower than an input voltage used by many conventional pulsed laser diode drivers. The bypass capacitor C_{BP} is a physical component added to the pulsed laser diode driver 301, or may be omitted if the drain capacitance of the bypass switch M_{BP} has a sufficient amount of capacitance.

In some embodiments, the DC input voltage Vᵢₙ is about 15 V, the inductance of the first bond wire L_{DL}¹ is about 1-2 nH, the inductance of the second bond wire L_{DL}² is about 1-2 nH, the capacitance of the source capacitor C_{S} is about 10-50 nF, the resistance of the damping resistor R_{Damp} is about 0.1 Ohms, and the capacitance of the bypass capacitor C_{BP} is about 1 nF.

Although it would initially appear that placing the source capacitor C_{S} in series with the laser diodes D_{L} would raise the required anode voltage to pulse the laser diodes D_{L}, the voltage and current of the source capacitor C_{S} are 90-degrees out of phase with one another. Because the current pulse through the laser diodes D_{L} is advantageously aligned with a peak current amplitude, voltage at the source capacitor C_{S} at that time is zero due to the 90-degree phase shift. In some embodiments, a beginning of the high-current pulse could be determined by sensing when the source voltage Vs at the source capacitor C_{S} is at zero, at which point the high-current pulse through the laser diodes D_{L} should begin.

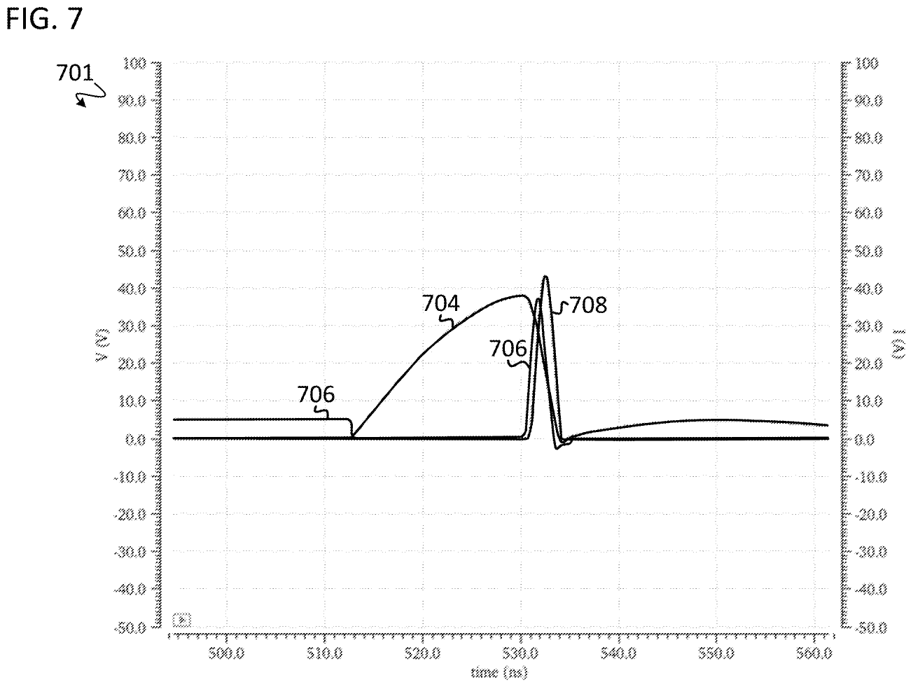

Operation of the pulsed laser diode driver 301 is explained in detail below with respect to a simplified plot 701 shown in FIG. 7 and is similar to or the same as the example switching sequence 900 that is shown in FIG. 9.

Though the respective inductances of L_{DL}¹⁻² are described herein as being advantageously implemented using bond wires, use of discrete inductors is not precluded. That is, in some embodiments, the circuit architecture of the pulsed laser diode driver 301 could use discrete inductors to implement the inductances of L_{DL}¹ and L_{DL}². For example, in some instances, the circuit architecture of the pulsed laser diode driver 301 may convey advantages (e.g., for achieving a particular current pulse width or current pulse amplitude through the laser diodes D_{L}) that are independent of whether the inductances of L_{DL}¹ and L_{DL}² are implemented using bond wires or discrete inductors.

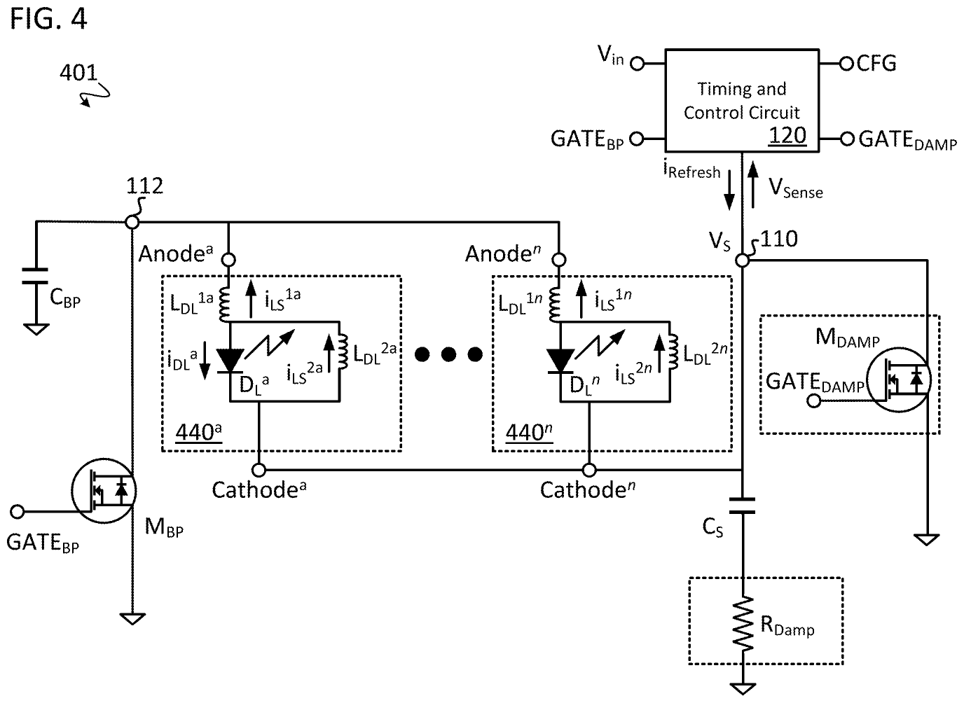

FIG. 4 is a simplified circuit schematic of a pulsed laser diode driver 401 of a fifth general topology to drive either two or more laser diode packages, or a single laser diode package having multiple laser diodes, in a common cathode arrangement, in accordance with some embodiments. Some components described above with reference to FIG. 3 are included in FIG. 4. The pulsed laser diode driver 401 generally includes the source capacitor C_{S}, the optional damping resistor R_{Damp}, the alternative optional damping resistor R′_{Damp}, two or more (or a single combined) laser diode packages 440^{a} through 440ⁿ, the bypass capacitor C_{BP}, the bypass switch M_{BP}, the timing and control circuit 120, the optional discharge switch M_{DAMP}, the timing and control circuit 120, nodes 110, 112, the refresh current i_{Refresh}, the voltage sense signal V_{Sense}, the DC input voltage Vᵢₙ, the source voltage V_{S} at the source capacitor C_{S}, the bypass switch gate driver signal GATE_{BP}, the configuration data CFG, and the discharge switch gate driver signal GATE_{DAMP}, connected as shown. In some embodiments, a respective capacitance of the bypass switch M_{BP} is of a sufficient value as to provide the bypass capacitance needed, and the bypass capacitor C_{BP} may therefore be omitted from the pulsed laser diode driver 401.

In some embodiments, each of the laser diode packages 440^{a-n} are individual laser diode packages. In other embodiments, the laser diode packages 440^{a-n} are part of a single package (e.g., a quad-pack) of laser diodes. In such embodiments, the cathode terminals Cathode^{a-n} may be implemented as a single pad or pin of the laser diode package (i.e., a common-cathode arrangement), and the anode terminals Anode^{a-n} may each be implemented as respective individual pads or pins of the laser diode package. In yet other embodiments, the anode terminals Anode^{a-n} may be implemented as a single pad or pin of the laser diode package (i.e., a common-anode arrangement), and the cathode terminals Cathode^{a-n} may each be implemented as respective individual pads or pins of the laser diode package. In still yet other embodiments, both the anode terminals Anode^{a-n} and the cathode terminals Cathode^{a-n} are implemented as respective single terminals so that all of the laser diodes D_{L}^{a-n} may be controlled in unison.

Of the two or more laser diode packages 440^{a-n}, the laser diode package 440^{a} includes one or more laser diodes D_{L}^{a}, each having a respective anode and cathode, a first bond wire L_{DL}^{1a}, a second bond wire L_{DL}^{2a}, an anode terminal Anode^{a}, and a cathode terminal Cathode^{a}. Though shown and referred to as respective single bond wires, as shown in FIGS. 10-11, in some embodiments, the first bond wire L_{DL}^{1a} may be implemented using a single bond wire, or two or more bond wires in parallel, to achieve a desired inductance value of the first bond wire L_{DL}^{1a}. Similarly, in some embodiments, the second bond wire L_{DL}^{2a} may be implemented using a single bond wire, or two or more bond wires in parallel, to achieve a desired inductance value of the second bond wire L_{DL}^{2a}.

The first bond wire L_{DL}^{1a} electrically connects the anodes of the laser diodes D_{L}^{a} to the anode terminal Anode^{a} of the laser diode package 440^{a}. The second bond wire L_{DL}^{2a} electrically connects the anodes of the laser diodes D_{L}^{a} to the cathodes of the laser diodes D_{L}^{a}. The cathodes of the laser diodes D_{L}^{a} are also electrically connected to the cathode terminal Cathode^{a} of the laser diode package 440^{a} (e.g., using bond wires (not shown) or by mounting on a conductive pad).

Of the two or more laser diode packages 440^{a-n}, the laser diode package 440ⁿ includes one or more laser diodes D_{L}ⁿ, each having a respective anode and cathode, a first bond wire L_{DL}¹ⁿ, a second bond wire L_{DL}²ⁿ, an anode terminal Anodeⁿ, and a cathode terminal Cathodeⁿ. Though shown and referred to as respective single bond wires, as shown in FIGS. 10-11, in some embodiments, the first bond wire L_{DL}¹ⁿ may be implemented using a single bond wire, or two or more bond wires in parallel, to achieve a desired inductance value of the bond wire L_{DL}¹ⁿ. Similarly, in some embodiments, the second bond wire L_{DL}²ⁿ may be implemented using a single bond wire, or two or more bond wires in parallel, to achieve a desired inductance value of the bond wire L_{DL}²ⁿ.

The first bond wire L_{DL}¹ⁿ electrically connects the anodes of the laser diodes D_{L}ⁿ to the anode terminal Anodeⁿ of the laser diode package 440ⁿ. The second bond wire L_{DL}²ⁿ electrically connects the anodes of the laser diodes D_{L}ⁿ to the cathodes of the laser diodes D_{L}ⁿ. The cathodes of the laser diodes D_{L}ⁿ are also electrically connected to the cathode terminal Cathodeⁿ of the laser diode package 440ⁿ (e.g., using bond wires (not shown) or by mounting on a conductive pad).

As shown in FIG. 4, a first terminal of the source capacitor C_{S} is configured to receive the refresh current i_{Refresh} from the timing and control circuit 120. The first terminal of the source capacitor C_{S} is directly electrically connected to the cathode terminals Cathode^{a-n} of the laser diode packages 440^{a-n} and is electrically coupled to a first terminal of the bypass capacitor C_{BP} and to a drain node of the bypass switch M_{BP} via the bond wires L_{DL}^{1a-1n} and L_{DL}^{2a-n}. A second terminal of the source capacitor C_{S} is directly electrically connected to a bias voltage node such as ground, or is electrically coupled to a bias voltage node such as ground through the optional damping resistor R_{Damp}. A second terminal of the optional damping resistor R_{Damp}, a second terminal of the discharge switch M_{DAMP}, and a second terminal of the bypass capacitor C_{BP} are directly electrically connected to a bias voltage node such as ground. The anode terminals Anode^{a-n} of the laser diode packages 440^{a-n} are directly electrically connected to the first terminal of the bypass capacitor C_{BP} and to a drain node of the bypass switch M_{BP}. A source node of the bypass switch M_{BP} is directly electrically connected to a bias voltage node such as ground.

The bypass switch M_{BP} is configured to receive the bypass switch gate driver signal GATE_{BP} at a gate node (e.g., from the timing and control circuit 120), the bypass switch gate driver signal GATE_{BP} being operable to turn the bypass switch M_{BP} on or off based on a voltage level of the bypass switch gate driver signal GATE_{BP}. Similarly, the discharge switch M_{DAMP} is configured to receive the discharge switch gate driver signal GATE_{DAMP} at a gate node (e.g., from the timing and control circuit 120), the discharge switch gate driver signal GATE_{DAMP} being operable to turn the discharge switch M_{DAMP} on or off based on a voltage level of the discharge switch gate driver signal GATE_{DAMP}.

Either or both of the bypass switch M_{BP} and/or the optional discharge switch M_{DAMP} can be implemented as N-type switches or P-type switches. In some embodiments, the bypass switch M_{BP} and/or the discharge switch M_{DAMP} are implemented as Silicon-based or Silicon-Carbide-based field-effect transistors (FETs).

In some embodiments, the pulsed laser diode driver 401 is configured to receive the DC input voltage Vᵢₙ having a voltage range from about 3.5 V to 45 V, which is advantageously lower than an input voltage used by many conventional pulsed laser diode drivers. In some embodiments, the bypass capacitor C_{BP} is a physical component added to the pulsed laser diode driver 401. In other embodiments, a drain capacitance of the bypass switch M_{BP} is of a sufficient capacitance value such that the bypass capacitor C_{BP} may be omitted from the pulsed laser diode driver 401.

In some embodiments, the DC input voltage Vᵢₙ is about 15 V, the inductance of the first bond wires L_{DL}^{a-n} is about 1-2 nH, the inductance of the second bond wires L_{DL}^{2a-n} is about 1-2 nH, the capacitance of the source capacitor C_{S} is about 10-50 nF, the resistance of the damping resistor R_{Damp} is about 0.1 Ohms, and the capacitance of the bypass capacitor C_{BP} is about InF.

The laser diode packages 130, 230^{a-n}, 340, and 440^{a-n} may be respectively referred to herein as an apparatus or a pulsed laser source. Similarly, the pulsed laser diode drivers 101, 151, 201, 301, and 401, which include one or more laser diode packages, may be respectively referred to herein as an apparatus or a pulsed laser source.

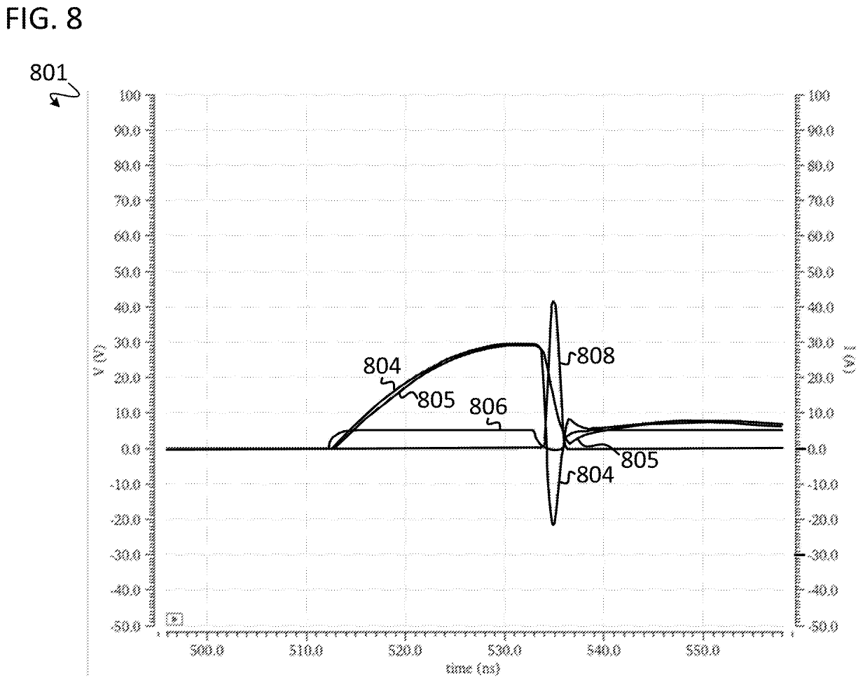

Operation of the pulsed laser diode driver 401 is explained in detail below with respect to a simplified plot 801 shown in FIG. 8 and is similar to or the same as the example switching sequence 900 that is shown in FIG. 9.

Though the respective inductances of LDL^{1a-2a} and L_{DL}¹ⁿ⁻²ⁿ are described herein as being advantageously implemented using bond wires, use of discrete inductors is not precluded. That is, in some embodiments, the circuit architecture of the pulsed laser diode driver 401 could use discrete inductors to implement the inductances of LDL^{1a-2a} and LDL¹ⁿ⁻²ⁿ. For example, in some instances, the circuit architecture of the pulsed laser diode driver 401 may convey advantages (e.g., for achieving a particular current pulse width or current pulse amplitude through the laser diodes D_{L}) that are independent of whether the inductances of L_{DL}^{1a-2a} and L_{DL}¹ⁿ⁻²ⁿ are implemented using bond wires or discrete inductors.

FIG. 5 shows simplified plots 501 of signals related to the operation of the pulsed laser diode driver 101 shown in FIG. 1A during an example switching sequence, in accordance with some embodiments. A plot 502 illustrates the voltage Vs at the source capacitor C_{S} during the example switching sequence, a plot 504 illustrates the current i_{LS}² through the second bond wires L_{DL}² during the example switching sequence, a plot 506 illustrates a level of the bypass switch gate driver signal GATE_{BP} during the example switching sequence, and a plot 508 illustrates the current i_{DL} through the one or more laser diodes D_{L} during the example switching sequence. As shown by the plot 504, the current i_{LS}² builds in the second bond wires L_{DL}² until the bypass switch M_{BP} is momentarily disabled by the bypass switch gate driver signal GATE_{BP}, at which time, as shown by the plot 508, a high-amplitude current peak of current i_{DL} (i.e., a resonant waveform) is directed through the laser diodes DL to emit a laser light pulse.

FIG. 6 shows simplified plots 601 of signals related to the operation of the pulsed laser diode driver 201 shown in FIG. 2 during an example switching sequence, in accordance with some embodiments. A plot 604 illustrates the total current i_{LS}^{2a-2n} through the second bond wires L_{DL}^{2a-n} during the example switching sequence, a plot 606 illustrates a level of one of the bypass switch gate driver signals GATE_{BP}^{a-n} during the example switching sequence, a plot 608 illustrates the total current i_{DL}^{a-n} through just one of the laser diode of the laser diodes D_{L}^{a-n} during the example switching sequence, and a plot 610 illustrates an example current, e.g., i_{DL}^{a}, through that laser diode. As shown by the plot 604, the current i_{LS}^{2a-n} builds in the second bond wires L_{DL}^{2a-n} until the associated bypass switch M_{BP}^{a-n} is momentarily disabled by the respective bypass switch gate driver signal GATE_{BP}^{a-n}, at which time, as shown by the plot 608, a high-amplitude current peak of current i_{DL}^{a-n} (i.e., a resonant waveform) is directed through the laser diode to emit a laser light pulse.

FIG. 7 shows simplified plots 701 of signals related to the operation of the pulsed laser diode driver 301 shown in FIG. 3 during an example switching sequence, in accordance with some embodiments. A plot 704 illustrates the current i_{LS}² through the second bond wires L_{DL}² during the example switching sequence, a plot 706 illustrates an anode voltage of the one or more laser diodes D_{L} during the example switching sequence, and a plot 708 shows the current i_{DL} through the one or more laser diodes D_{L} during the example switching sequence. As shown by the plot 704, the current i_{LS}² builds in the second bond wires L_{DL}² until the bypass switch M_{BP} is momentarily disabled by the bypass switch gate driver signal GATE_{BP} (not shown), at which time, as shown by the plot 708, a high-amplitude current peak of current i_{DL} (i.e., a resonant waveform) is directed through the laser diodes D_{L} to emit a laser light pulse.

FIG. 8 shows simplified plots 801 of signals related to the operation of the pulsed laser diode driver 401 shown in FIG. 4 during an example switching sequence, in accordance with some embodiments. A plot 804 illustrates the current i_{LS}^{2a} through the second bond wires L_{DL}^{2a} during the example switching sequence, a plot 805 illustrates the current i_{LS}^{1a} through the first bond wires L_{DL}^{1a} during the example switching sequence, a plot 806 illustrates a level of the bypass switch gate driver signal GATE_{BP} during the example switching sequence, and a plot 808 illustrates the current i_{DL}^{a} (i.e., a resonant waveform) through the one or more laser diodes D_{L}^{a} during the example switching sequence. As shown by the simplified plots 801, current flows through the bond wires L_{DL}^{1a} and L_{DL}²a during the bypass pulse such that the current i_{LS}^{2a} flows through the laser diodes D_{L}^{a} and the current i_{LS}^{1a} charges the bypass capacitor C_{BP} until the current reverses and the current i_{LS}^{1a} also flows through the laser diodes D_{L}^{a}.

FIG. 9 illustrates a portion of an example switching sequence 900 for operation of the pulsed laser diode driver 101 shown in FIG. 1A, in accordance with some embodiments. However, the switching sequence 900 is similar to, or the same as, respective switching sequences related to the operation of other embodiments of the pulsed laser diode drivers disclosed herein.

At a precharge step 901, the bypass switch M_{BP} and the laser diode switch M_{DL} are off (i.e., not conducting). During the precharge step 901, the source capacitor C_{S} is charged by the refresh current i_{Refresh} generated by the timing and control circuit 120. At a preflux step 902, the bypass switch M_{BP} and the laser diode switch MDI are transitioned to an ON-state, thereby allowing the currents i_{LS}¹⁻² to flow through the bond wires L_{DL}¹⁻² to store energy in the form of magnetic flux therein. Even though both of the switches (M_{DL}, M_{BP}) are in an ON-state at the preflux step 902, the bypass path through the bypass switch M_{BP} will carry all of the current i_{LS}¹⁻² because a bandgap voltage of the laser diode D_{L} needs to be overcome to allow current to flow through the laser diode D_{L}.

In some embodiments, the laser diode switch MDI is transitioned to an ON-state after the bypass switch M_{BP} is transitioned to an ON-state. At a pulse generation step 903, the bypass switch M_{BP} is transitioned to an OFF-state while the laser diode switch M_{DL} is maintained in an ON-state, thereby generating the high-current pulse through the laser diode D_{L}. As disclosed herein, the bypass switch M_{BP} is transitioned to the OFF-state upon a determination by the timing and control circuit 120 that the currents i_{DL}¹⁻² through the bond wires L_{DL}¹⁻² is at, or is close to, a maximum current amplitude. During the pulse generation step 903, the refresh current i_{Refresh} is not generated by the timing and control circuit 120. When the bypass switch M_{BP} is transitioned to the OFF-state, voltage at the anode of the laser diode D_{L} rises quickly, until the bandgap voltage of the laser diode DI is overcome and the laser diode D_{L} begins to conduct current. Because of a resonant circuit formed by the bypass capacitor C_{BP} and the bond wires L_{DL}¹⁻² of the laser diode D_{L}, the voltage formed at the anode of the laser diode D_{L} will advantageously rise as high as necessary to overcome the bandgap voltage of the laser diode D_{L} and will generally be higher than the source voltage Vs.

At a discharge step 904, the bypass switch M_{BP} and the laser diode switch M_{DL} are maintained in an ON-state to drain charge stored at the source capacitor C_{S} to advantageously eliminate a high voltage spike at the anode of the laser diode D_{L} when the laser diode switch M_{DL} is transitioned to an OFF-state. During the discharge step 904, the refresh current i_{Refresh} is not generated by the timing and control circuit 120. In embodiments that include the optional discharge switch M_{DAMP} and the alternate optional damping resistor R′_{Damp} that is shown in FIG. 1A, the discharge switch M_{DAMP} is enabled via the discharge switch gate driver signal GATE_{DAMP} during the discharge step 904 to rapidly discharge the source capacitor C_{S}. The discharge switch M_{DAMP} is disabled during steps 901, 902, 903, and 905.

At step 905, the bypass switch M_{BP} and the laser diode switch M_{DL} are transitioned to an OFF-state, thereby returning to the precharge state at step 901. Because the source voltage Vs at the source capacitor C_{S} is completely discharged at the end of the discharge step 904, there is very little current through the laser diode D_{L}. Thus, there is advantageously very little overshoot when the switches M_{DL}, and M_{BP} are transitioned to the OFF-state at step 905, thereby preventing damage to the laser diode D_{L} and the switches M_{DL}, and M_{BP}. The time interval of the overall pulse and bypass signals is selected, in some embodiments, such that the source capacitor C_{S} is fully discharged before the switches M_{DL}, and M_{BP} are transitioned to the OFF-state at step 905.

FIG. 10 is a simplified, top-down orthoscopic view of a portion of a printed circuit board (PCB) or laser diode package 1000 of the pulsed laser diode drivers shown in FIGS. 1A-2, in accordance with some embodiments.

The PCB or laser diode package 1000 includes one or more laser diodes 1001, a first anode terminal 1002a, a second anode terminal 1002b, a common cathode terminal 1004, and bond wires 1006a-b. Also shown are dimensions 1008a-b. The PCB 1000 is configured to control all of the laser diodes 1001 in unison using the anode terminals 1002a-b. In some embodiments, the PCB or laser diode package 1000 is a portion of a direct die on printed circuit board device and the terminals 1002a-b and 1004 are pads of a PCB board. In other embodiments, the PCB or laser diode package 1000 is a portion of a discrete encapsulated laser diode package and the terminals 1002a-b and 1004 are portions of a lead-frame of the laser diode package.

In the embodiment shown, a respective cathode terminal (not shown) of the laser diodes 1001 is mounted on, and directly electrically connected to, the cathode terminal 1004. A respective anode terminal of the laser diodes 1001 (the topside shown) is electrically connected to the anode terminals 1002a-b via the bond wires 1006a-b. Thus, with reference to FIG. 1A, the cathode terminal corresponds to the cathode terminal labeled “Cathode”, the anode terminal 1002a corresponds to the anode terminal Anode¹, the anode terminal 1002b corresponds to the anode terminal Anode², the laser diodes 1001 correspond to the laser diodes D_{L}, the bond wires 1006a implement the bond wires L_{DL}¹, and the bond wires 1006b implement the bond wires L_{DL}². In the embodiment shown, the bond wires 1006a-b are configured to be of the same length 1008a-b to thereby configure the inductances of the bond wires L_{DL}¹ and L_{DL}² to be equal.

FIG. 11 is a simplified, top-down orthoscopic view of a portion of a printed circuit board (PCB) or laser diode package 1100 of the pulsed laser diode drivers shown in FIGS. 3-4, in accordance with some embodiments. The PCB or laser diode package 1100 includes a quad-pack 1101 of laser diodes 1101a-d, a common anode pad 1102, a common cathode pad 1104, and bond wires 1106a-c. Also shown are dimensions 1108a-b. The PCB or laser diode package 1100 is configured to control all of the laser diodes 1101a-d in unison using the common anode pad 1102. However, in other embodiments, the laser diodes 1101a-d may be individually controlled using a respective anode pad per laser diode. In some embodiments, the PCB or laser diode package 1100 is a portion of a direct die on printed circuit board device and the pads 1102 and 1104 are pads of a PCB board. In other embodiments, the PCB or laser diode package 1100 is a portion of a discrete encapsulated laser diode package and the pads 1102 and 1104 are portions of a lead-frame of the laser diode package.

In the embodiment shown, a respective cathode terminal (not shown) of the laser diodes 1101a-d is mounted on, and directly electrically connected to, the common cathode pad 1104. A respective anode terminal of the laser diodes 1101a-d (the topside shown) is electrically connected to the anode pad 1102 via the bond wires 1106a and electrically connected to the common cathode pad 1104 via the bond wires 1106b-c. Thus, with reference to FIG. 4, the common anode pad 1102 corresponds to the node 112, the common cathode pad 1104 corresponds to the node 110, the laser diodes 1001a-d correspond to the laser diodes D_{L}^{a-n}, the bond wires 1106a implement the bond wires LDL^{1a-1n}, and the bond wires 1106b-c implement the bond wires L_{DL}^{2a-2n}. In the embodiment shown, the bond wires 1106a-c are configured to be of the same length 1108a-b to thereby configure the inductances of the bond wires L_{DL}^{1a-1n} and L_{DL}^{2a-2n} to be equal.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A pulsed laser diode driver comprising:
a source capacitor having i) a first terminal configured to receive a refresh current and to develop a source voltage therefrom, and ii) a second terminal electrically coupled to ground;
a first laser diode package comprising a first anode terminal, a first cathode terminal, a first laser diode, a first bond wire, and a second bond wire, wherein a cathode of the first laser diode is directly electrically connected to the first cathode terminal, an anode of the first laser diode is directly electrically connected to a first end of the first bond wire and to a first end of the second bond wire, a second end of the first bond wire being directly electrically connected to the first anode terminal, and a second end of the second bond wire being electrically connected to the first terminal of the source capacitor;
a bypass capacitor having a first terminal directly electrically connected to the first anode terminal of the first laser diode package;
one or more switches configured to control a current flow through the first bond wire and the second bond wire; and
a timing and control circuit configured to generate one or more gate driver signals to control the one or more switches to produce a high-current pulse through the first laser diode, the high-current pulse corresponding to a peak current of a resonant waveform developed at the anode of the first laser diode.

2. The pulsed laser diode driver of claim 1, further comprising:
a damping resistor that couples the second terminal of the source capacitor to ground.

3. The pulsed laser diode driver of claim 1, further comprising:
a discharge switch having a drain node that is electrically coupled to the first terminal of the source capacitor and a source node that is electrically coupled to ground;
wherein:
the discharge switch is configured to discharge energy stored at the source capacitor after the high-current pulse is produced through the first laser diode.

4. The pulsed laser diode driver of claim 1, wherein:
the first laser diode package further comprises a second anode terminal;
the second end of the second bond wire is directly electrically connected to the second anode terminal; and
the second anode terminal is directly electrically connected to the first terminal of the source capacitor.

5. The pulsed laser diode driver of claim 1, wherein:
the second end of the second bond wire is directly electrically connected to the cathode of the first laser diode; and
the first cathode terminal is directly electrically connected to the first terminal of the source capacitor.

6. The pulsed laser diode driver of claim 1, further comprising:
a second laser diode package comprising a second anode terminal, a second cathode terminal, a second laser diode, a third bond wire, and a fourth bond wire, wherein a cathode of the second laser diode is directly electrically connected to the second cathode terminal, an anode of the second laser diode is directly electrically connected to a first end of the third bond wire and to a first end of the fourth bond wire, a second end of the third bond wire being directly electrically connected to the second anode terminal, and a second end of the fourth bond wire being electrically connected to the first terminal of the source capacitor;
wherein:
the second anode terminal of the second laser diode package is directly electrically connected to the first terminal of the bypass capacitor;
the one or more switches are configured to control a current flow through the third bond wire and the fourth bond wire; and
the timing and control circuit is configured to generate one or more gate driver signals to control the one or more switches to produce a high-current pulse through the second laser diode, the high-current pulse corresponding to a peak current of a resonant waveform developed at the anode of the second laser diode.

7. The pulsed laser diode driver of claim 6, wherein:
the second laser diode package further comprises a third anode terminal;
the second end of the fourth bond wire of the second laser diode package is directly electrically connected to the third anode terminal; and
the third anode terminal is directly electrically connected to the first terminal of the source capacitor.

8. The pulsed laser diode driver of claim 6, wherein:
the second end of the fourth bond wire of the second laser diode package is directly electrically connected to the cathode of the second laser diode; and
the second cathode terminal is directly electrically connected to the first terminal of the source capacitor.

9. An apparatus, comprising:
a first anode terminal, a second anode terminal, and a cathode terminal;
a laser diode having an anode and a cathode, the cathode being electrically connected to the cathode terminal;
a first bond wire having a first end that is directly electrically connected to the anode of the laser diode and a second end that is directly electrically connected to the first anode terminal; and
a second bond wire having a first end that is directly electrically connected to the anode of the laser diode and a second end that is directly electrically connected to the second anode terminal.

10. The apparatus of claim 9, further comprising:
a source capacitor having i) a first terminal directly electrically connected to receive a refresh current and to develop a source voltage therefrom, and ii) a second terminal electrically coupled to ground;
a bypass capacitor having a first terminal and a second terminal, the second terminal being directly electrically connected to ground; and
a bypass switch and a laser diode switch configured to control a current flow through the first bond wire and the second bond wire;
wherein:
a drain node of the bypass switch is directly electrically connected to the first terminal of the bypass capacitor and a source node of the bypass switch is directly electrically connected to ground;
the first anode terminal is directly electrically connected to the first terminal of the bypass capacitor;
the second anode terminal is directly electrically connected to the first terminal of the source capacitor; and
the cathode terminal is directly electrically connected to a drain node of the laser diode switch, a source node of the laser diode switch being directly electrically connected to ground.

11. The apparatus of claim 10, further comprising:
a damping resistor that couples the second terminal of the source capacitor to ground.

12. The apparatus of claim 10, further comprising:
a timing and control circuit configured to generate one or more gate driver signals to control the bypass switch and the laser diode switch to produce a high-current pulse through the laser diode, the high-current pulse corresponding to a peak current of a resonant waveform developed at the anode of the laser diode.

13. The apparatus of claim 12, further comprising:
a discharge switch having a drain node that is electrically coupled to the first terminal of the source capacitor and a source node that is electrically coupled to ground;
wherein:
the discharge switch is configured to discharge energy stored at the source capacitor after the high-current pulse is produced through the laser diode.

14. An apparatus, comprising:
an anode terminal and a cathode terminal;
a laser diode having an anode and a cathode, the cathode being electrically connected to the cathode terminal;
a first bond wire having a first end that is directly electrically connected to the anode of the laser diode and a second end that is directly electrically connected to the anode terminal; and
a second bond wire having a first end that is directly electrically connected to the anode of the laser diode and a second end that is electrically connected to the cathode of the laser diode.

15. The apparatus of claim 14, further comprising:
a source capacitor having i) a first terminal directly electrically connected to receive a refresh current and to develop a source voltage therefrom, and ii) a second terminal electrically coupled to ground;
a bypass capacitor having a first terminal and a second terminal, the second terminal being directly electrically connected to ground; and
a bypass switch configured to control a current flow through the first bond wire and the second bond wire;
wherein:
a drain node of the bypass switch is directly electrically connected to the first terminal of the bypass capacitor and a source node of the bypass switch is directly electrically connected to ground;
the anode terminal is directly electrically connected to the first terminal of the bypass capacitor and the drain node of the bypass switch; and
the cathode terminal is directly electrically connected to the first terminal of the source capacitor.

16. The apparatus of claim 15, further comprising:
a damping resistor that couples the second terminal of the source capacitor to ground.

17. The apparatus of claim 15, further comprising:
a timing and control circuit configured to generate one or more gate driver signals to control the bypass switch to produce a high-current pulse through the laser diode, the high-current pulse corresponding to a peak current of a resonant waveform developed at the anode of the laser diode.

18. The apparatus of claim 17, further comprising:
a discharge switch having a drain node that is electrically coupled to the first terminal of the source capacitor and a source node that is electrically coupled to ground;
wherein:
the discharge switch is configured to discharge energy stored at the source capacitor after the high-current pulse is produced through the laser diode.
